(19) United States
(12) Patent Application Publication
(10) Pub. No.: US 2024/0047244 A1
(43) Pub. Date: Feb. 8, 2024

(54) LIQUID PROCESSING APPARATUS AND LIQUID PROCESSING METHOD

(71) Applicant: Tokyo Electron Limited, Tokyo (JP)

(72) Inventors: Koki YOSHIMURA, Kumamoto (JP); Hayato HOSAKA, Kumamoto (JP)

(21) Appl. No.: 18/231,378

(22) Filed: Aug. 8, 2023

(30) Foreign Application Priority Data
Aug. 8, 2022 (JP) 2022-126575

(51) Int. Cl. H01L 21/67; H01L 21/02; H01L 21/687

(52) U.S. Cl. CPC H01L 21/6715; H01L 21/67051; H01L 21/02052; H01L 21/68764

(57) ABSTRACT

A liquid processing apparatus provided with a plurality of processors, wherein each of the processors includes a stage on which a substrate is placed, a cup surrounding the stage and the substrate placed thereon, a first processing nozzle and a second processing nozzle configured to supply a first and second processing liquid to the substrate, respectively, a first standby portion where the first processing nozzle stands by, a second standby portion where the second processing nozzle stands by, a first mover configured to move the first processing nozzle between the first standby portion and a first processing position, a second mover configured to move the second processing nozzle between the second standby portion and a second processing position, and a guide shared by the first mover and the second mover such that each of the first mover and the second mover moves in the left-right direction.

### CROSS-REFERENCE TO RELATED APPLICATION

This application is based upon and claims the benefit of priority from Japanese Patent Application No. 2022-126575, filed on Aug. 8, 2022, the entire contents of which are incorporated herein by reference.

### TECHNICAL FIELD

The present disclosure relates to a liquid processing apparatus and a liquid processing method.

### BACKGROUND

In a semiconductor device manufacturing process, a semiconductor wafer (hereinafter, referred to as a “wafer”) is processed by supplying various processing liquids. Patent Document 1 discloses an apparatus for supplying a developer as a processing liquid to wafers stored in respective cups arranged side by side.

### PRIOR ART DOCUMENT

### Patent Document

Patent Document 1: Japanese Patent Laid-Open Publication No. 2012-15385

### SUMMARY

According to one embodiment of the present disclosure, there is provided a liquid processing apparatus provided with a plurality of processors arranged in a left-right direction, wherein each of the processors includes a stage on which a substrate is placed, a cup surrounding the stage and the substrate placed on the stage, a first processing nozzle and a second processing nozzle configured to supply a first processing liquid and a second processing liquid to the substrate, respectively, a first standby portion where the first processing nozzle is allowed to stand by on one of left and right sides of the cup, a second standby portion where the second processing nozzle is allowed to stand by on the other of the left and right sides of the cup, a first mover configured to move the first processing nozzle between the first standby portion and a first processing position above the substrate, a second mover configured to move the second processing nozzle between the second standby portion and a second processing position above the substrate, and a guide shared by the first mover and the second mover such that each of the first mover and the second mover moves in the left-right direction.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view of a developing apparatus according to a first embodiment of the present disclosure.

FIG. 2 is a vertical side view of the developing apparatus.

FIG. 3 is a vertical cross-sectional front view of cup provided in the developing apparatus.

FIG. 4 is a vertical cross-sectional side view of the cup.

FIG. 5 is a perspective view of the upper side of the cup.

FIG. 6 is a schematic plan view illustrating an exhaust path for exhausting the cup.

FIG. 7 is a schematic view illustrating an image acquired for a nozzle provided in the processor.

FIG. 8 is a schematic view illustrating an image acquired for the processor.

FIG. 9 is a vertical cross-sectional side view of the cup.

FIG. 10 is a vertical cross-sectional side view of the cup.

FIG. 11 is an explanatory view illustrating the effect of the developing apparatus.

FIG. 12 is a plan view of a developing apparatus according to a second embodiment of the present disclosure.

FIG. 13 is a vertical cross-sectional side view of a cup provided in the developing apparatus of the second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

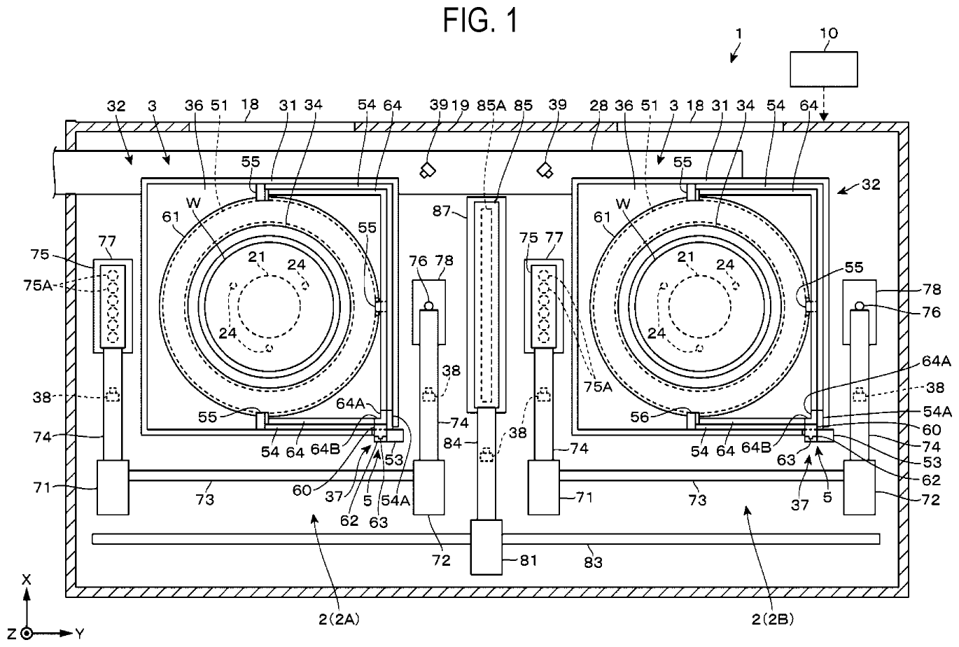

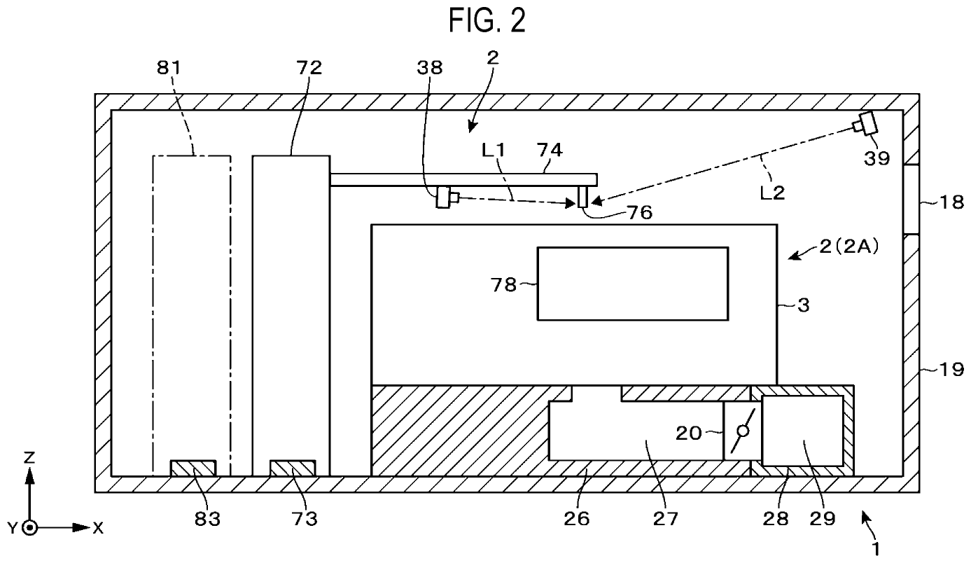

The outline of a developing apparatus 1 according to a first embodiment of the present disclosure will be described first with reference to a plan view of FIG. 1 and a schematic side view of FIG. 2. A wafer W, which is a circular substrate, is transported to the developing apparatus 1 by a transport mechanism (not illustrated). A resist film is formed on the surface of the wafer W, which is exposed along a predetermined pattern. The resist film is formed of, for example, a positive resist, and the developing apparatus 1 performs development process of the resist film by supplying a positive resist developer (positive developer) to the surface of the wafer W and cleaning process after the development process by supplying cleaning liquid to the surface of the wafer W. These processes are performed by ejecting a developer and a cleaning liquid as processing liquids from a developing nozzle (developer nozzle) and a cleaning nozzle (cleaning liquid nozzle), respectively.

The developing apparatus 1 includes two cups 3 which store and process wafers W, respectively, and the wafers W can be individually processed for respective cups 3. Outside of the cups 3, standby portions are provided to make the above-mentioned nozzles on standby, respectively, when not in use. The nozzles each move between a position where a processing liquid is ejected from a space above a wafer W stored in a cup 3 (processing position) and a standby portion by a mover to which the nozzle is connected. In the developing apparatus 1, a mover shared between the two cups 3 and dedicated movers for the cups 3 are provided, and two dedicated movers are provided for each cup. Therefore, three movers can be used for one cup 3 to move the nozzles for processing.

As long as the developer and the cleaning liquid can be supplied to the wafers W in respective cups 3, the type or shape of a processing liquid to be ejected from the nozzle connected to each mover is arbitrary. In the example illustrated in FIG. 1, of the three movers used for one cup 3, a cleaning nozzle is connected to one dedicated mover, and the other one dedicated mover and the shared mover are connected to developing nozzles having different shapes. That is, one cup 3 is provided with two types of developing nozzles, and one of them can be selected for development process.

The developing apparatus 1 will be described in detail below. The developing apparatus 1 includes a housing 19, an exhaust duct 28, two processors 2, a mover 81 shared between the two processors 2, developer nozzles 75 and 85, and a cleaning liquid nozzle 76. The processors 2 each include a cup 3 and movers 71 and 72 dedicated to the cup 3. The developer nozzles 75 and 85 and the cleaning liquid nozzle 76 may be simply referred to as nozzles 75, 85 and 76, respectively.

The housing 19 is formed in a quadrilateral shape and has rectangular shape with long sides extending in the left-right direction in a plan view. In the side wall on the rear side of the housing 19, transport ports 18 for carry-in/out of wafers W are formed to be separated in the left-right direction from each other, and a transport mechanism (not shown) provided outside the housing 19 enters the housing 19 through each transport port 18 and transports the wafers W to a processor 2 in the housing 19. Unless otherwise specified, the left and right sides in the following description refer to the left and right sides when viewed from the front to the rear. The front-rear direction and the left-right direction are indicated as the X direction and the Y direction, respectively, in the drawings. In addition, a vertical direction (perpendicular direction) orthogonal to each of the X direction and the Y direction is indicated as the Z direction. The X, Y, and Z directions are orthogonal to each other.

The two processors 2 are provided to be separated in the left-right direction from each other in the housing 19, and include pin chucks 21 and the like that form stages on which wafers W are placed, in addition to the above-described cups 3 and the like. The two processors 2 are configured similarly to each other, and the processor 2 on the left is sometimes denoted as 2A and the processor 2 on the right is sometimes denoted as 2B. The processors 2A and 2B are one processor and another processor, respectively. In addition, since each component, such as the cup 3, included in each of the processors 2A and 2B is configured in the same manner, between the processors 2A and 2B, the same components are arranged side by side and located at the same height.

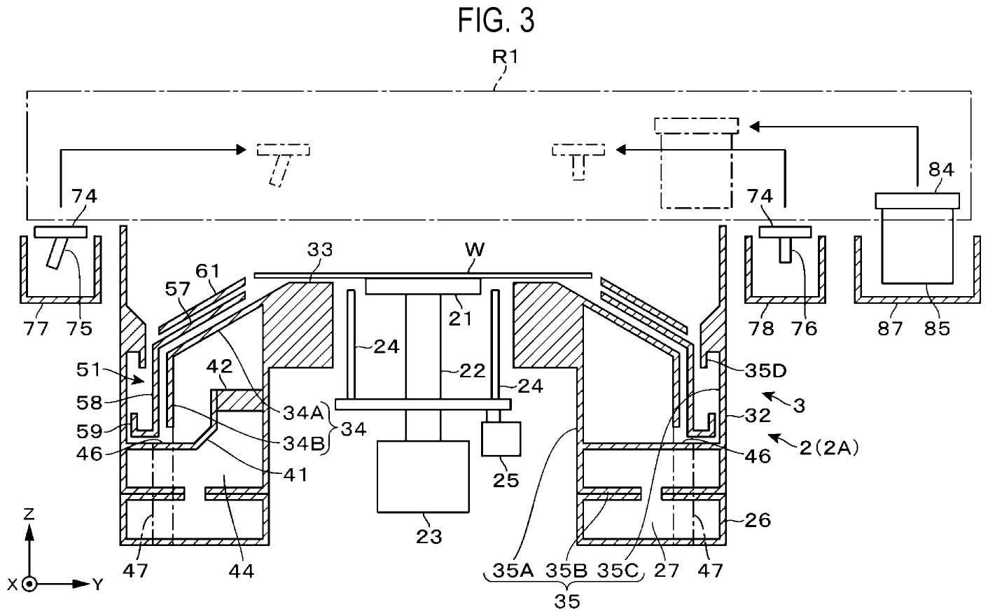

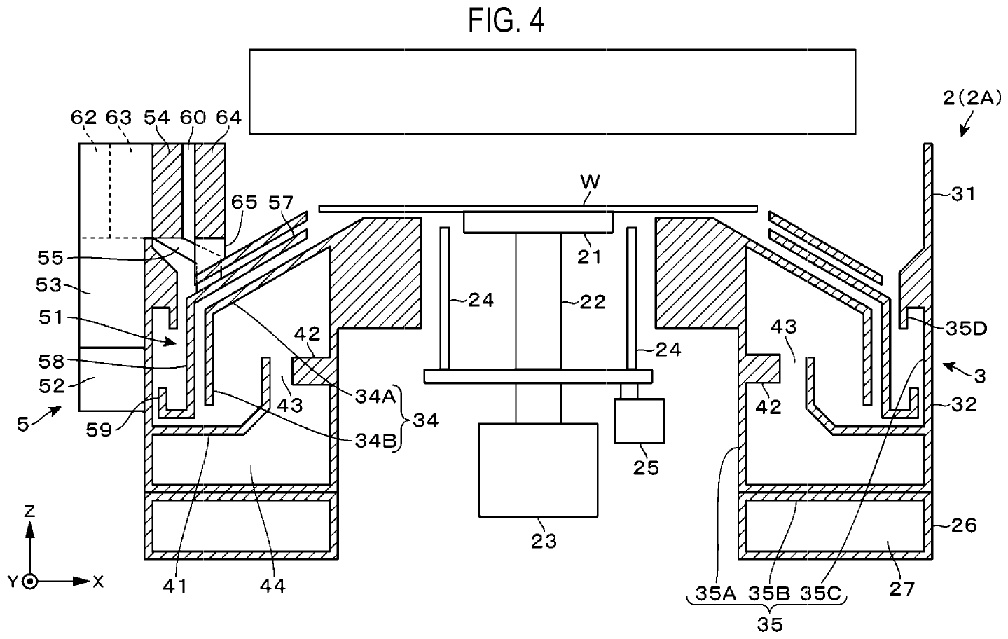

Hereinafter, the processor 2A will be described as a representative of the processors 2A and 2B with reference to the vertical cross-sectional front view of FIG. 3 and the vertical cross-sectional side view of FIG. 4. The above-described spin chuck 21 has a circular shape and is arranged in front of the transport port 18 so as to be able to perform delivery to and from the transport mechanism. A central portion of the bottom surface of the wafer W is placed on the spin chuck 21, and the spin chuck 21 vacuum-suctions the central portion of the bottom surface. As a result, the wafer W is held horizontally on the spin chuck 21. The spin chuck 21 is supported on the upper end of a vertically extending shaft 22. The lower end side of the shaft 22 is connected to a rotary mechanism 23, which rotates the spin chuck 21 together with the held wafer W around a vertical axis.

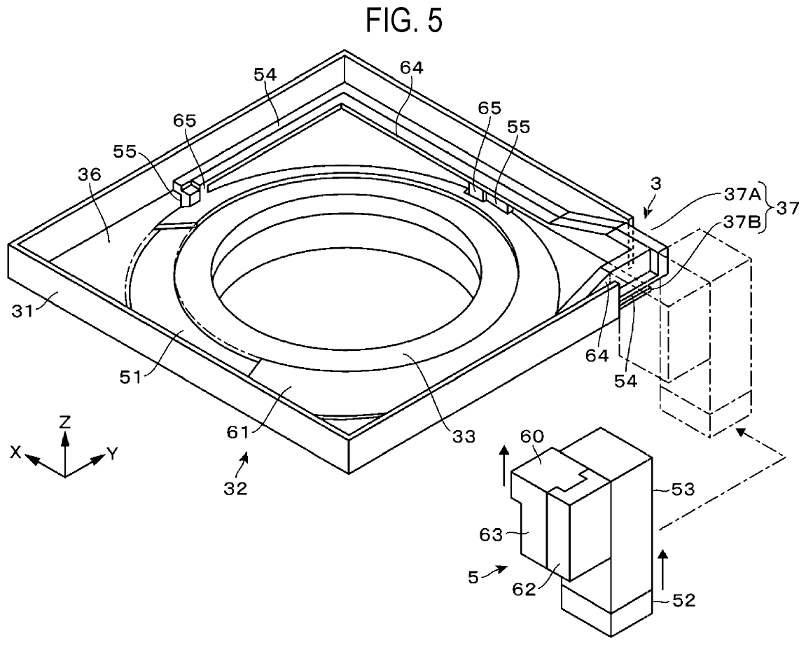

A cup 3 is provided to surround the side circumference of the wafer W held by the spin chuck 21. Therefore, the spin chuck 21 is provided inside the cup 3. The interior of the cup 3 is exhausted, and droplets and mist of the processing liquid supplied to the wafer W are prevented from scattering outside the cup 3. Referring to the perspective view of the upper side of the cup 3 in FIG. 5, the cup 3 also includes a cup main body 32 with a quadrilateral perimeter wall 31, a lower circular annular portion 51, and an upper circular annular portion 61. In a plan view, the quadrilateral perimeter wall 31, the lower circular annular portion 51, and the upper circular annular portion 61 surround the wafer W suctioned to the spin chuck 21. The upper circular annular portion 61 overlaps the lower circular annular portion 51 from a space above the lower circular annular portion 51, and the quadrilateral perimeter wall 31, which is a quadrilateral body in a plan view, overlaps the lower circular annular portion 51, which is a first annular body, and the upper circular annular portion 61, which is a second circular annular body. In addition, in FIG. 5, for convenience of illustration, a portion of the circumference of the upper circular annular portion 61 is cut away to show the lower circular annular portion 51.

Each of the lower circular annular portion 51 and the upper circular annular portion 61 can be lifted with respect to the quadrilateral perimeter wall 31, and, by the lifting, is switched among a first state, a second state, and a third state of which the heights are different from each other with respect to the cup 3. The first state has the lowest height and the third state has the highest height. The switching among the first to third states is performed to prevent the nozzle to be used and the wafer W transport mechanism from interfering with the cup 3, and to adjust the height of the cup 3 extending upward from the wafer W to an appropriate height to prevent mist and droplets from flowing out of the cup 3 depending on the process to be performed on the wafer W (i.e., depending on the nozzle to be used).

Hereinafter, the cup 3 will be described in more detail. The cup main body 32 constituting the cup 3 includes, in addition to the quadrilateral perimeter wall 31, a lower wall portion 33, a guide portion 34, and an annular recess 35 (see FIGS. 3 and 4). The lower wall portion 33 is formed in an annular shape to surround the shaft 22, and the peripheral edge of the upper side of the lower wall portion 33 is drawn outward to form the guide portion 34. The guide portion 34 is constituted with an inclined wall 34A drawn out obliquely downward from the lower wall portion 33 toward the outside to have a top surface forming an inclined surface, and a cylindrical vertical wall 34B extending vertically downward from the peripheral end of the inclined wall 34A. The guide portion 34 has a role of causing the adhered droplets to flow down to drainage port 46 opening in a partition wall 41, which will be described later.

The lower side of the peripheral edge of the lower wall portion 33 is drawn vertically downward to form a cylindrical inner wall 35A, the lower end of the inner wall 35A is widened toward the outside of the cup main body 32 to form an annular bottom wall 35B, and the peripheral edge of the bottom wall 35B extends upward to form a cylindrical outer wall 35C. The annular recess 35 is formed by these inner wall 35A, bottom wall 35B, and outer wall 35C. The upper portion of the outer wall 35C bulges inward, and the inner end of the bulging portion protrudes downward to form an annular sealing projection 35D.

In addition, the upper end of the outer wall 35C is located above the lower wall portion 33, and a portion of the periphery of the outer wall portion 35C is widened outward to form a liquid receiving portion 36 having a square shape in a plan view (see FIGS. 1 and 5), and the peripheral end of this liquid receiving portion 36 extends vertically upward, forming the above-described quadrilateral perimeter wall 31. Since each portion is configured as described above, the region surrounded by the upper end of the outer wall 35C and the region surrounded by the lower wall portion 33 form an opening of the cup main body 32.

One side forming the quadrilateral perimeter wall 31 that is square in a plan view and the other side adjacent to the one side are formed in the front-rear direction (the X direction) and the left-right direction (the Y direction), respectively, and a notch 37 is formed at the front and right corner of the quadrilateral perimeter wall 31 in a plan view. Therefore, the notch 37 is formed over two sides of the four sides forming the outer shape of the quadrilateral perimeter wall 31 in a plan view. In the notch 37, the portion extending in the front-rear direction and the portion extending in the left-right direction may be denoted as 37A and 37B, respectively.

Regarding the lower side of the outer wall 35C, a side of the inner peripheral surface of the outer wall 35C lower than the position where the sealing projection 35D is provided protrudes toward the inner side of the cup 3 to form a partition wall 41 that separates the upper and lower spaces in the cup 3. The partition wall 41 is bent upward on the way to the inner wall 35A, and the upper end of the partition wall 41 is in contact with a flange 42 provided on the peripheral surface of the inner wall 35A. Upward exhaust ports 43 are formed at intervals in the circumferential direction of the flange 42 and are open above the lower end of the vertical wall 34B of the guide portion 34 so as to prevent the inflow of the processing liquid. An exhaust space 44 is surrounded and defined by the partition wall 41 and the bottom wall 35B of the annular recess 35, and the exhaust space 44 is set to a negative pressure as described later, so that the exhaust from the exhaust ports 43 is performed. In addition, a drainage port 46 is open on the peripheral edge side of the partition wall 41, and the processing liquid flowing into the drainage port 46 passes through a flow path forming portion 47 connected to the drainage port 46 and flows out of the cup 3 and is removed.

A composite lifting mechanism 5 is provided outside the cup main body 32 (see FIGS. 4 and 5). The composite lifting mechanism 5 includes a first base portion 52, a first lifter 53, a second base portion 62, and a second lifter 63, and the position of the first base portion 52 is fixed with respect to the cup main body 32. The first lifter 53 is provided on the first base portion 52 so as to be vertically raised and lowered with respect to the base portion 52. The first lifter 53 and the first base portion 52 correspond to a first lifting mechanism.

The second base portion 62 and the second lifter 63 constitute a second lifting mechanism, and the second base portion 62 and the second lifter 63 are provided, for example, on the left side of the first lifter 53. In addition, the second lifter 63 is located on the rear side of the second base portion 62, and the second base portion 62 is fixed to the first lifter 53, and the second lifter 63 can be raised and lowered in the vertical direction with respect to the first lifter 53. As will be described in detail below, the first lifter 53 is connected to the lower circular annular portion 51 to be raised and lowered together, and the second lifter 63 is connected to the upper circular annular portion 61 to be raised and lowered together. In the following, a description will be continued with reference to FIGS. 3 to 5. In this description, it is assumed that the first lifter 53 and the second lifter 63 are in the state of being located at lower positions in their respective lifting ranges. In this state, the lower circular annular portion 51 and the upper circular annular portion 61 are located at the lower positions in their respective lifting ranges, thereby staying at the above-described first state. Thus, the description with reference to FIGS. 3 to 5 is a description on the first state.

Each of the left end portion of the first lifter 53 and the second lifter 63 faces the notch 37B from the outside of the quadrilateral perimeter wall 31. Two outer support arms 54 extend from the left end portion of the first lifter 53 to the inner side of the quadrilateral perimeter wall 31 through the notch 37B, wherein one of the outer support arms 54 is directed leftward and the other is directed rearward. The outer support arm 54, which is directed rearward, is bent leftward after encountering the quadrilateral perimeter wall 31. By extending in this way, the two outer support arms 54 are formed along the quadrilateral perimeter wall 31. The base end of the outer support arm 54 extending rearward is higher than the other portion and is formed as a high portion 54A facing the notch 37A. Three first support portions 55 extending downward are provided on the outer support arms 54 to be spaced apart from each other, and are located on the front, rear, and right sides, respectively, with respect to the center of the cup main body 32. The lower circular annular portion 51 is supported by these first support portions 55.

The lower circular annular portion 51 includes an inclined wall 57, of which the diameter is decreased upward so that the top surface thereof forms an inclined surface, and a barrel portion 58 extending vertically from the lower end of the inclined wall 57. Each of the inclined wall 57 and the barrel portion 58 is configured in a cylindrical shape. Since the top surface of the inclined wall 57 is connected to the first support portion 55 at the positions of the peripheral ends which are separated from each other, the lower circular annular portion 51 is supported by the outer support arms 54. The lower end portion of the barrel portion 58 is folded outward to form a circular annular sealing recess 59. Regarding the positional relationship between the lower circular annular portion 51 and the cup main body 32, the inclined wall 57 of the lower circular annular portion 51 is located slightly above the inclined wall 34A, and the inner peripheral edge of the inclined wall 57 is located above the inclined wall 34A. The barrel portion 58 is located between the vertical wall 34B and the outer wall 35C of the cup main body 32 with separations therebetween. The sealing recess 59 is located below the sealing projection 35D.

Next, the second lifter 63 will be described in detail. The rear side of the second lifter 63 protrudes slightly into the quadrilateral perimeter wall 31 through the notch 37B to form a protrusion 60 that passes over the outer support arms 54. The right end portion of the protrusion 60 extends rearward and the left end portion thereof extends leftward to form inner support arms 64, respectively. The inner support arm 64, which is directed rearward, is bent leftward after encountering the outer support arms 54. By extending in this manner, two inner support arms 64 are located closer to the center of the cup main body 32 with respect to the outer support arms 54, and are formed along the direction of extension of the outer support arms 54, i.e., along the quadrilateral perimeter wall 31.

The base end portion of each inner support arm 64 is higher than the other portions, thereby forming high portions 64A and 64B facing notches 37A and 37B, respectively, and the high portions 64A and 64B are connected to each other at a corner portion of the quadrilateral perimeter wall 31. Therefore, the notch 37A is blocked by overlapping of the high portion 64A of the inner support arms 64 and the high portion 54A of the outer support arms 54, and the notch 37B is blocked by overlapping of the protrusion 60 of the second lifter 63 and the high portion 64B of the inner support arms 64. More specifically, when seeing the respective portions (high portions 64A, 64B, and 54A and protrusion 60) that block (close) the notches 37 and the quadrilateral perimeter wall 31 together, a perimeter is formed as if there is no notch and surrounds the entire circumferences of the lower circular annular portion 51 and the upper circular annular portion 61 in a plan view.

The portions that block (close) the notches 37 may also be referred to as a lifting member for raising and lowering the lower circular annular portion 51 or the upper circular annular portion 61. That is, the quadrilateral perimeter wall 31 having a notch and the lifting member that raises and lowers the members inside the quadrilateral perimeter wall 31 (the lower circular annular portion 51 and the upper circular annular portion 61) form an annulus as described above, thereby forming an annular liquid receiving portion that receives mist and droplets generated inside the annulus and prevents the mist and droplets from flowing out to the outside. In addition, as an example of the present embodiment, the annular liquid receiving portion is located higher than the spin chuck 21 which is a stage, and is the highest liquid receiving portion in the cup 3.

Three second support portions 65 extending downward are provided on the inner support arms 64 to be spaced apart from each other, and are located on the front, rear, and right sides, respectively, with respect to the center of the cup main body 32. The upper circular annular portion 61 is supported by these second support portions 65. By having a diameter that is decreased upward, the upper circular annular portion 61 is formed in a cylindrical shape with an inclined top surface. The peripheral end of the top surface is connected to the second support portion 65 at positions spaced apart from each other. A notch is formed in a portion of the peripheral edge of the upper circular annular portion 61, and the first support portions 55 are connected to the lower circular annular portion 51 through this notch.

The upper circular annular portion 61 is located slightly above the lower circular annular portion 51. In a plan view, the inner peripheral edge of the upper circular annular portion 61 and the inner peripheral edge of the lower circular annular portion 51 overlap each other. More specifically, the inner peripheral edge of the upper circular annular portion 61 and the inner peripheral edge of the lower circular annular portion 51 are located on the inclined wall 34A of the cup main body 32 below the upper end of the quadrilateral perimeter wall 31. In addition, the lower end of the upper circular annular portion 61 is located above the lower side of the inclined wall 57 of the lower circular annular portion 51.

The cup main body 32 will be additionally described with reference to FIG. 4. Three vertical pins 24 are provided around the spin chuck 21 in a plan view and pass through the lower wall portion 33 of the cup main body 32, and can be raised and lowered by a lifting mechanism 25. A wafer W is delivered between the above-described transport mechanism and the spin chuck 21 by raising and lowering the pins 24. The cup main body 32 is supported on a circular base body 26, and the lateral circumference of the lower portion of the cup main body 32 and the lateral circumference of the base body 26 are aligned with each other. The base body 26 is provided with an exhaust path 27, which is connected to the exhaust space 44 in the cup main body 32 via a communication passage. Exhaust from the exhaust duct 28, which will be described in detail later, brings the exhaust path 27 and the exhaust space 44 into a negative pressure.

Next, the mover 71 as the first mover and the mover 72 as the second mover will be described. A guide rail 73 is provided as a guide member that horizontally extends in the left-right direction in front of the cup 3, and the movers 71 and 72 are connected to the guide rail 73. The movers 71 and 72 are movable in the left-right direction on the front side of the cup 3 along the extending direction of the guide rail 73. Arms 74 extend rearward from the movers 71 and 72, respectively. Each arm 74 can be raised and lowered by one of the movers 71 and 72 that serves as an extension source. A developer nozzle 75 and a cleaning liquid nozzle 76 are provided on the tip side of the arm 74 extending from the mover 71 and the tip side of the arm 74 extending from the mover 72, respectively.

The developer nozzle 75 includes a plurality of ejection holes 75A arranged in the front-rear direction, and each ejection hole 75A is, for example, bored obliquely, so that the developer can be ejected downward obliquely to the left. The cleaning liquid nozzle 76 ejects the cleaning liquid vertically downward. A left standby portion 77 and a right standby portion 78 are provided on the left and right sides of the cup 3. The left standby portion 77 and the right standby portion 78 have a box shape with an open top. The nozzles are carried into and out of the space in the box by a lifting operation, and the carried-in nozzles are put on standby.

The left standby portion 77 as the first standby portion is used for standby of the developer nozzle 75 as the first nozzle, and the right standby portion 78 as the second standby portion is used for standby of the cleaning liquid nozzle 76 as the second nozzle. The left standby portion 77 and the right standby portion 78 may be simply referred to as standby portions 77 and 78. Since the guide rail 73 is shared by the movers 71 and 72 as a guide for the movers 71 and 72, the developer nozzle 75 can be moved from the inside of the left standby portion 77 to the upper side of the right end portion of the cup 3, and the cleaning liquid nozzle 76 can be moved from the inside of the right standby portion 78 to the upper side of the left end portion of the cup 3. The developer ejected from the developer nozzle 75 and the cleaning liquid ejected from the cleaning liquid nozzle 76 are a first processing liquid and a second processing liquid, respectively. Therefore, the types of the first processing liquid and the second processing liquid are different. In this specification, when the constituent components are different, the types of processing liquids are different. Therefore, a positive developer and a negative developer, each of which is used in development process, are also processing liquids of different types.

As described above, the guide rail 73 is provided to be shared by the movers 71 and 72. The same portion of the guide rail 73 is used by the movers 71 and 72 at different times. Specifically, when a wafer W is processed, each of the developer nozzle 75 and the cleaning liquid nozzle 76 will be moved to the space above the central portion of the wafer W. In moving each of the developer nozzle 75 and the cleaning liquid nozzle 76 to the upper side of the central portion of the wafer W, since each of the movers 71 and 72 is moved to the central portion of the guide rail 73 in the longitudinal direction, the central portion will be used to guide these movers 71 and 72 at different times.

Next, the mover 81 shared by the processors 2A and 2B will be described. A guide rail 83 is provided in front of the guide rails 73 of the processors 2A and 2B, and the guide rail 83 horizontally extend in the left-right direction from the front left end portion of the cup 3 of the processor 2A to the front right end portion of the cup 3 of the processor 2B. The mover 81, which is a third mover, is connected to the guide rail 83 and is movable in the left-right direction on the front side of each of the movement regions of the movers 71 and 72 along the extension direction of the guide rail 83. Therefore, the mover 81 moves in the left-right direction between the front side of the cup 3 of the processor 2A and the front side of the cup 3 of the processor 2B.

An arm 84 extends rearward from the mover 81 and can be raised and lowered by the mover 81. A developer nozzle 85 is provided on the tip side of the arm 84. The developer nozzle 85, which is the third processing nozzle, has a slit-shaped ejection port 85A elongated in the front-rear direction and is capable of ejecting the developer as a third processing liquid vertically downward.

A standby portion 87 is provided between the right standby portion 78 of the processor 2A and the left standby portion 77 of the processor 2B. Therefore, regarding the processor 2A, the standby portion 87 is provided on the side opposite to the side where the spin chuck 21 is provided with respect to the right standby portion 78 in the left-right direction, and regarding the processor 2B, the standby portion 87 is provided on the side opposite to the side where the spin chuck 21 is provided with respect to the left standby portion 77 in the left-right direction. The standby portion 87 has the same configuration as the left standby portion 77 and the right standby portion 78 except that the standby portion 87 is configured to have a size capable of accommodating the developer nozzle 85. The developer nozzle 85 can be moved from the inside of the standby portion 87 to the upper side of the left end portion of the cup 3 of the processor 2A and can be moved from the inside of the standby portion 87 to the upper side of the right end portion of the cup 3 of the processor 2B. The mover 81, the guide rail 83, the arm 84, the developer nozzle 85, and the standby portion 87 may be respectively referred to as a shared mover 81, a shared guide rail 83, a shared arm 84, a shared developer nozzle 85, and a shared standby portion 87 in order to distinguish them from the movers, the arms, the developer nozzles, and the standby portions dedicated to the processor 2A or 2B.

The developer nozzle 75, the cleaning liquid nozzle 76, and the shared developer nozzle described so far are respectively provided on arms so that each of the nozzles is able to supply a processing liquid to a region from the peripheral edge portion to the central portion of a wafer W by lateral movement. The developer nozzle 75 and the shared developer nozzle 85 are connected to a developer source, and the cleaning liquid nozzle 76 is connected to a cleaning liquid source so that supply and stop of the developer or the cleaning liquid are performed from each source. Illustration of each source is omitted.

The developer nozzle 75, the cleaning liquid nozzle 76, and the shared developer nozzle are accommodated in the left standby portion 77, the right standby portion 78, and the shared standby portion 87, respectively, when not in use. Each of the developer nozzle 75, the cleaning liquid nozzle 76, and the shared developer nozzle 85 will be used by being raised from the accommodated standby portion, then being moved in the left-right direction to the upper side of the cup 3, and being lowered to the processing position on the wafer W. The height of the processing position from the wafer W differs depending on the nozzle. As described above, in the movement between the upper side of the cup 3 and the standby portion, the height at which the developer nozzle 75 moves in the left-right direction, the height at which the cleaning liquid nozzle 76 moves in the left-right direction, and the height at which the shared developer nozzle move in the left-right direction overlap each other. That is, the predetermined height is the height at which each of the nozzles 75, 76, and 86 moves. The height at which each of these nozzles moves in the left-right direction is collectively indicated as a movement region R1 in FIG. 3.

The upper end of each of the standby portions 77, 78, and 87 is located lower than the upper end of the cup 3 (the upper end of the quadrilateral perimeter wall 31) when each of the nozzles 75, 76, and 85 moves in the left-right direction between the standby portion and the upper side of the cup. When a nozzle moves in the left-right direction as described above, such arrangement of the standby portions 77, 78, and 87 contributes to preventing the moving nozzle from interfering with a nozzle in the standby state and the arm supporting the nozzle in the standby state. As a specific example, when the shared developer nozzle 85 moves to the cups 3 of the processors 2A and 2B, the shared developer nozzle 85 is movable without interfering with the cleaning liquid nozzle 76, which stands by in the right standby portion 78 of the processor 2A, the developer nozzle 75, which stands by in the left standby portion 77 of the processor 2B, and the arms 74, which support these nozzles.

The setting of the lateral movement region R1 of each nozzle and the setting of the heights of the standby portions 77, 78, and 87 contribute to reducing the height of the developing apparatus 1. The reduction in height enables a large number of developing apparatuses 1 to be stacked and arranged in a limited space, so that the throughput of the system in which the developing apparatuses 1 are mounted can be improved.

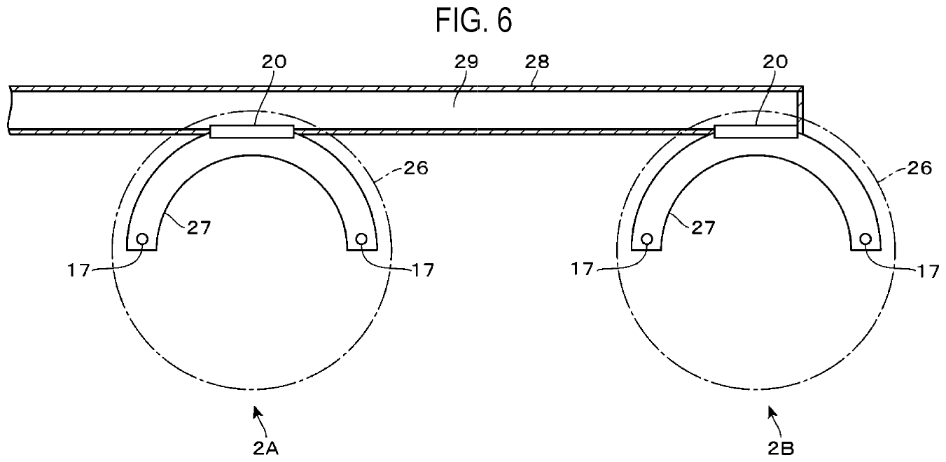

Next, the exhaust duct 28, which is an exhaust path forming member, will be described with reference to the plan view of FIG. 6 as well. The exhaust duct 28 extends in the left-right direction on the rear side of the cups 3 of the processors 2A and 2B and is connected to the rear side of the base body 26 of each of the processors 2A and 2B. The downstream side of the exhaust duct 28 is directed leftward and faces the outside of the housing 19. The downstream side of an in-duct exhaust path 29 formed in the exhaust duct 28 is connected to an exhaust path of the factory where the developing apparatus 1 is installed. Therefore, the in-duct exhaust path 29 is provided to extend from the rear side of the cup 3 at the left end portion (one end) among the cups 3 arranged side by side to the rear side of the spin chuck 21 at the right end portion (the other end).

The exhaust path 27 formed in each of the base bodies 26 described above is formed in an arc shape in a plan view to follow the peripheral edge of the cup 3 on the rear side of the cup 3, and the central portion of this arc is connected to the in-duct exhaust path 29 via a damper 20. Therefore, the interior of each cup 3 is connected to the exhaust path 29. For example, exhaust is always performed in the in-duct exhaust path 29, and the amount of exhaust from each cup 3 is adjusted by the damper 20. Due to the above configuration, the exhaust path for exhausting each cup 3 is common to the processors 2A and 2B on the downstream side, and the upstream side is formed as an exhaust path provided with a damper 20 for each of the processors 2A and 2B. Specifically, in the in-duct exhaust path 29, a position to the left from the position where the exhaust path 27 of the processor 2A is connected is an exhaust path shared by the processors 2A and 2B.

As described above, the exhaust duct 28 is arranged on the rear side of each cup 3, that is, the side opposite to the side on which the movers 71, 72, and 81 for moving the nozzles are arranged in the front-rear direction. As a result, the movers 71, 72, and 81 do not need to be arranged above the exhaust duct 28. Therefore, this layout of the exhaust duct 28 is advantageous in suppressing the height of the developing apparatus 1.

The developing apparatus 1 is provided with cameras 38 and 39, and images acquired by the cameras 38 and 39 are transmitted to a controller 10, which will be described later, and are used to determine whether there is an abnormality in the apparatus. Returning back to FIGS. 1 and 2, these cameras 38 and 39 will be described. In order to distinguish these cameras from each other, the camera 38 may be referred to as a nozzle imaging camera 38 and the camera 39 as an in-cup imaging camera.

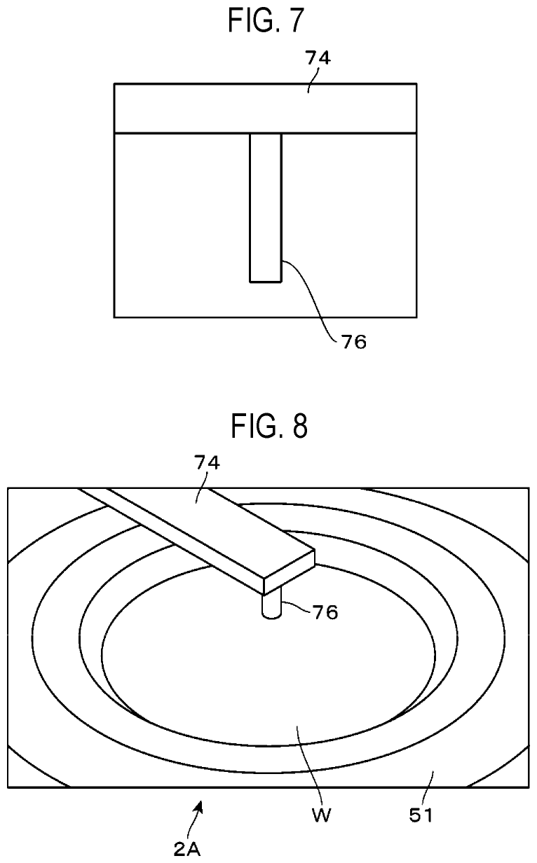

Each arm 74 and the shared arm 84 are provided with a nozzle imaging camera 38. Each nozzle imaging camera 38 is arranged so that its optical axis L1 is directed rearward and obliquely downward. That is, the optical axis L1 extends along the X direction and is inclined with respect to the Y and Z directions. In addition, the nozzle imaging camera 38 is able to image the nozzle supported by the arm on which the nozzle imaging camera 38 is provided. FIG. 7 illustrates an example of an image acquired by the nozzle imaging camera 38 of the arm 74 on which the cleaning liquid nozzle 76 is provided.

Two in-cup imaging cameras 39 are provided, wherein one of the in-cup imaging cameras is used for imaging the interior of the cup 3 of the processor 2A and the other is used for imaging the interior of the cup 3 of the processor 2B. Each camera 39 is able to image the stage (the spin chuck 21), a wafer W, and various nozzles positioned inside the corresponding cup 3. In addition, the camera 39 may be adjusted to an angle of view capable of imaging the opening end portion of the cup 3 and the outer wall outside thereof. The two in-cup imaging cameras 39 are located above the cups 3, respectively. In a plan view, the in-cup imaging cameras 39 are located between the cup 3 of the processor 2A and the cup 3 of the processor 2B in the left-right direction and at the rear side of the respective cups 3 in the front-rear direction. The in-cup imaging camera 39 for the processor 2A is arranged so that the optical axis L2 thereof can be directed obliquely downward and to the left front, and the optical axis L2 for the in-cup imaging camera 39 for the processor 2B is arranged so that the optical axis L2 thereof can be directed obliquely downward and to the right front. Therefore, the optical axis L2 of each in-cup imaging camera 39 is tilted with respect to each of the X, Y, and Z directions.

With the above-described arrangement, the in-cup imaging camera 39 is capable of capturing an overhead image of the surface of the wafer W. Therefore, the controller 10 is capable of determining whether there is an abnormality in the processing state of the surface of the wafer W based on the acquired image. In addition, when the developer nozzle 75, the shared developer nozzle 85, or the cleaning liquid nozzle 76 is located above the wafer W in processing the wafer W, these nozzles are within the field of view of the in-cup imaging camera 39, so that imaging becomes possible. FIG. 8 illustrates an example of an image of the cleaning liquid nozzle 76 acquired by the in-cup imaging camera 39 of the processor 2A. As described above, the in-cup imaging camera 39 is arranged to be capable of imaging a relatively wider range on the wafer W so that an abnormality on the surface of the wafer W can be detected. Therefore, for the same nozzle, the sizes in the images, which are acquired by the cameras 38 and 39, respectively, will be different from each other, and the nozzle will appear larger in the image acquired by the nozzle imaging camera 38. The camera 39 is located above the cup 3, but regardless of the movement of nozzles to be imaged, it may be always located above the nozzles. By doing so, droplets and mist scattered from the nozzles are less likely to adhere thereto, making it easier to continue imaging with good image quality.

Each of the developer nozzle 75, the shared developer nozzle 85, and the cleaning liquid nozzle 76 is imaged by the in-cup imaging camera 39 when having moved to a predetermined position within the field of view of the in-cup imaging camera 39. In addition, the nozzle imaged by the in-cup imaging camera 39 is also imaged by the nozzle imaging camera 38 at an arbitrary time. Then, by using the images acquired respectively from the nozzle imaging camera 38 and the in-cup imaging camera 39, the controller 10 determines whether there is an abnormality in the nozzle from which the images have been acquired. This abnormality includes, for example, a change in shape due to breakage or the like, deviation from a normal position on the arm, adhesion of the processing liquid to the surface of the nozzle, or dripping of the processing liquid from the ejection holes of the nozzle, or the like.

For example, when an attempt is made to determine whether a nozzle is abnormal from an image acquired by using only one of the nozzle imaging camera 38 as a first imager and the in-cup imaging camera 39 as a second imager, there is a concern that it is difficult to distinguish the image from the normal state since the image is captured from only one direction. Specifically, for example, it is assumed that an abnormality, such as adhesion of droplets or a broken portion on a front surface in an imaging direction, has occurred in a nozzle. In that case, since the outer shape and position of the nozzle detected from the image are the same as the outer shape and position of the nozzle in a normal state, there is a concern that it is difficult to make a determination on an abnormality. In addition, even when the above-mentioned adhesion of droplets or a broken portion has occurred on the surface of a nozzle opposite to the imaging direction, there is a concern that it is difficult to accurately determine an abnormality because it becomes a blind spot in imaging.

As described above, the direction in which the optical axis L1 of the nozzle imaging camera 38 is oriented and the direction in which the optical axis L2 of the in-cup imaging camera 39 is oriented are not parallel to each other but intersect each other. That is, the directions of the optical axes L1 and L2 are not the same as nor opposite to each other in the XYZ coordinate system, and imaging is performed from the crossing directions. Therefore, compared to an abnormality that occurs on the front surface or the rear surface of a nozzle in the imaging direction when only one camera is used, determination with higher accuracy is possible. From the viewpoint of improving the detection accuracy of an abnormality by imaging a nozzle from different directions, for example, it is preferable that the imaging time of the nozzle imaging camera 38 and the imaging time of the in-cup imaging camera 39 be simultaneous, but there may be a deviation between the times.

Returning back to FIG. 1, the developing apparatus 1 includes a controller 10. The controller 10 is configured with a computer and has a program. The program incorporates a group of steps so that a series of operations in the developing apparatus 1 can be performed. Based on the program, the controller 10 outputs a control signal to each part of the developing apparatus 1 so as to control the operation of each part. Specifically, each operation, such as rotation of the spin chuck 21 by the rotary mechanism 23, raising/lowering of the pins 24 by the lifting mechanism 25, supply of a processing liquid from a processing liquid source to each nozzle, movement of the nozzle by each mover, or raising/lowering of the lower circular annular portion 51 and the upper circular annular portion 61 by the composite lifting mechanism 5, is controlled by the above control signal. The above-mentioned program is stored in a non-transitory computer-readable storage medium such as a compact disk, a hard disk, or a DVD, and is installed in the controller 10.

The above-mentioned program is configured to be able to perform a determination on whether there is an abnormality on the surface of a wafer W based on an image transmitted by the in-cup imaging camera 39, and a determination on whether there is an abnormality on each of the nozzles 75, 76, and 85 based on images transmitted by the nozzle imaging camera 38 and the in-cup imaging camera 39 as well. The controller 10 includes a notifier that, when it is determined that there is an abnormality, outputs an alarm to notify the user of the fact, and this outputting of the alarm is also performed by a program. In addition, the alarm is, for example, display of a predetermined screen or sound.

Next, the first to third states of a cup 3 will be described in more detail. When processing is performed by the shared developer nozzle 85, when a wafer W is delivered between the transport mechanism and the spin chuck 21 via the pins 24, and when each of the nozzles 75, 76, and 85 moves between the standby portion and the processing position above the wafer W, the above-described first state is established.

When performing processing with the developer nozzle 85 shown in FIG. 4, a developer is ejected from the developer nozzle 85 while the developer nozzle 85 is moving in the left-right direction, and the developer is supplied onto the surface of the wafer W, the liquid receiving portion 36 of the cup main body 32, and the upper circular annular portion 61. The developer supplied to each part in this way flows down onto the partition wall 41, in which the drainage port 46 are formed, through the gap formed by the cup main body 32, the lower circular annular portion 51, and the upper circular annular portion 61, and is removed from the drainage port 46. During this, a pool of the developer formed on the liquid receiving portion 36, and droplets and mist, which are generated by being repelled from the position where the developer is supplied, are received by the quadrilateral perimeter wall 31 and the members blocking the above-described notches 37 in the quadrilateral perimeter wall 31, and flow into the drainage port 46 through the gap without leaking to the outside of the quadrilateral perimeter wall 31.

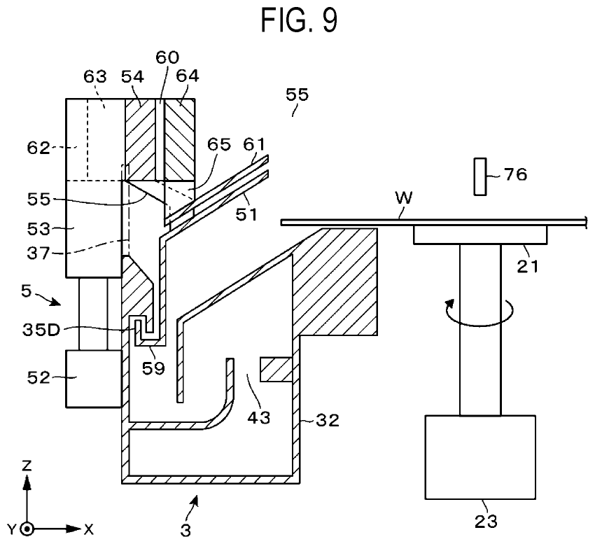

Next, the second state of the cup 3 will be described with reference to FIG. 9. The second state is the state in which the first lifter 53 is located at the upper position in the lifting range, while the second lifter 63 is located at the lower position in the lifting range as in the first state. As described above, since the second lifter 63 is provided to the first lifter 53 so that both the upper circular annular portion 61 and the lower circular annular portion 51 are raised and lowered together, and both the upper circular annular portion 61 and the lower circular annular portion 51 are located higher in the second state than in the first state, and the inner peripheral end of the lower circular annular portion 51 is disposed above the wafer W on the spin chuck 21. In the second state, the sealing projection 35D of the cup main body 32 enters the sealing recess 59 of the lower circular annular portion 51, so that exhaust is not performed from the outer circumference of the lower circular annular portion 51 and exhaust is performed from the opening of the lower circular annular portion 51 in a sufficient amount, thereby preventing the mist from flowing out from the opening.

This second state is established when processing by the cleaning liquid nozzle 76 is performed and when drying (shaking off cleaning liquid) is performed. The cleaning liquid is ejected from the cleaning liquid nozzle 76 toward the center of the wafer W, while the wafer W rotates. Droplets and mist scattered from the wafer W are received by the inner peripheral surface of the inclined wall 57 of the lower circular annular portion 51, turn into droplets, and flow down onto the partition wall 41 along the inner peripheral surface of the barrel portion 58, and are removed from the drainage port 46. Even when drying the wafer W after the ejection of the cleaning liquid from the cleaning liquid nozzle 76 is stopped, droplets and mist scattered from the wafer W are similarly removed.

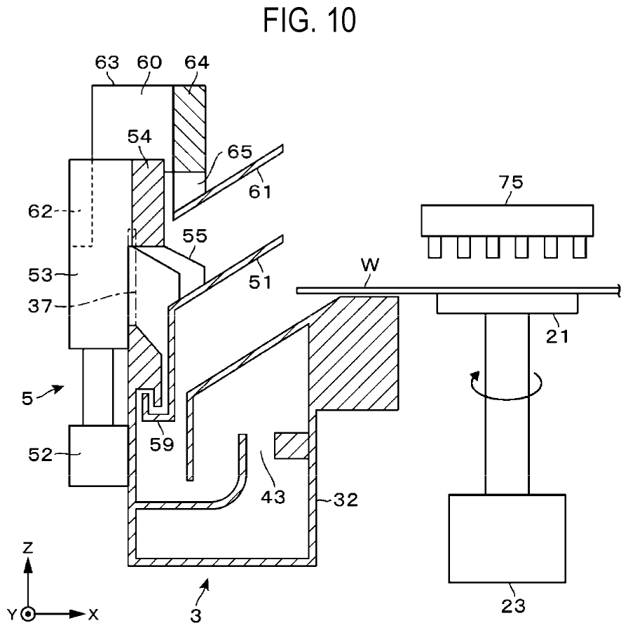

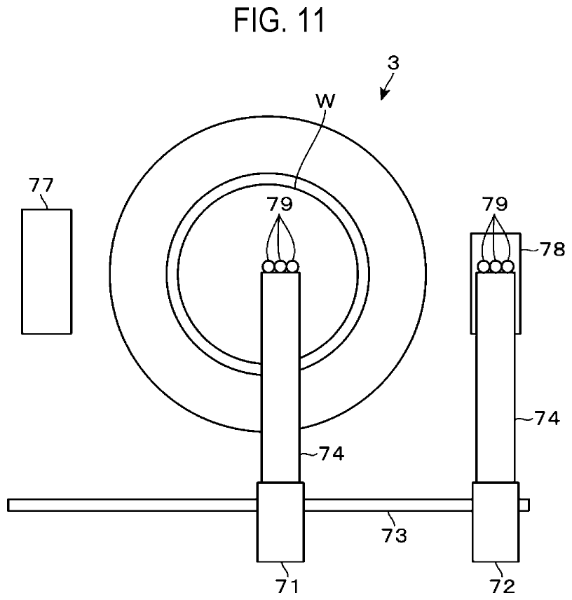

The third state of the cup 3 will be described with reference to FIG. 10. The third state is the state in which both the first lifter 53 and the second lifter 63 are located at the upper positions in their respective lifting ranges, and the upper circular annular portion 61 is located higher in the third state than in the second state. This third state is established when processing by the developer nozzle 75 is performed.

As the wafer W rotates, the shared developer nozzle 85 moves in the left-right direction while ejecting the developer, and the developer supply position moves from the peripheral edge of the rotating wafer W toward the central portion, whereby development process is performed. As in the second state, the droplets and mist scattered from the wafer W and received by the inner peripheral surface of the inclined wall 57 of the lower circular annular portion 51 turn into droplets on the inner peripheral surface and are removed from the drainage port 46. Among the droplets and mist, those scattered toward a higher place are received by the inner peripheral surface of the upper circular annular portion 61, turn into droplets, fall onto the top surface of the lower circular annular portion 51, flow downward along the outer peripheral surface of the lower circular annular portion 51, and are accumulated in the sealing recess 59.

In the second state and the third state, when the outer support arm 54, the inner support arm 64, and the second lifter 63, which blocked the notches 37 in the quadrilateral perimeter wall 31 in the first state, move upward, the notches 37 are opened. However, as described above, because the lower circular annular portion 51 has the role of preventing the processing liquid from leaking out of the cup 3 in the second state and the lower circular annular portion 51 and the upper circular annular portion 61 have the role in the third state, the processing liquid is prevented from flowing out of the cup 3 even when the notches 37 are opened.

As described above, the developing apparatus 1 is provided with the first lifter 53 and the second lifter 63 that move up and down outside the quadrilateral perimeter wall 31. In addition, a first connector (the high portion 54A of the outer support arm 54) connecting the first lifter 53 and the lower circular annular portion 51, and a second connector (the high portions 64A and 64B of the inner support arm 64 and the protrusion 60) connecting the second lifter 63 and the upper circular annular portion 61 block the notches in the quadrilateral perimeter wall 31 only when necessary. For example, it may also be conceivable to form a quadrilateral perimeter wall 31 without a notch, and to provide each of the first connector, which connects the first lifter 53 and the lower circular annular portion 51, and the second connector, which connects the second lifter 63 and the upper circular annular portion 61, to pass above the quadrilateral perimeter wall 31. However, in such a configuration, the height of the apparatus is increased by the connectors. That is, the configuration of the developing apparatus 1 in which the notches 37 are provided and the notches 37 are blocked by the first and second connectors when necessary is desirable in that the height of the apparatus can be reduced so that the number of installations in a limited space can be increased, as described above.

It may be also conceivable to adopt a configuration in which the quadrilateral perimeter wall 31 is not provided with a notch, and the quadrilateral perimeter wall 31 and the lower circular annular portion 51 are connected to the same lifting mechanism provided outside the cup 3 so that both the quadrilateral perimeter wall 31 and the circular annular portion 51 are raised and lowered (a cup configuration of a comparative example). However, in order to make the distance between the wafer W and the developer nozzle 85 appropriate in the first state, the upper end of the quadrilateral perimeter wall 31 is located above the upper end of the lower circular annular portion 51. Therefore, when the upper circular annular portion 61 is located at the upper position, it is considered that the upper end of the quadrilateral perimeter wall 31 is located at a position higher than the upper end of the upper circular annular portion 61. That is, compared with the cup configuration of the comparative example, the configuration in which the notches 47 in the quadrilateral perimeter wall 31 are blocked when necessary as described above is preferable in that the height of the developing apparatus 1 can be reduced.

In addition, it is preferable to provide both the first connector and the second connector to pass through the notches 37 (that is, to block the notches 37), to connect the first lifter 53 and the lower circular annular portion 51, and to connect the second lifter 63 and the upper circular annular portion 61. However, the connection may be made by allowing only one of the first connector and the second connector to pass through the upper side of the quadrilateral perimeter wall 31 without passing through the notches 37. That is, a configuration may be adopted in which the notches 37 are opened and closed by only the other one of the first connector and the second connector. However, in order to reduce the height of the apparatus, it is advantageous to close the notches 37 with both the first connector and the second connector, as described above.

Next, the processing of a wafer W in the processor 2A will be described following a sequence. First, it is assumed that processing using the shared developer nozzle 85 among the developer nozzles 75 and 85 is performed. Further, it is assumed that, in the processor 2A, the cup 3 is in the first state described with reference to FIGS. 3 to 5 and the developer nozzle 75, the cleaning liquid nozzle 76, and the shared developer nozzle 85 are on standby in the left standby portion 77, the right standby portion 78, and the shared standby portion 87, respectively.

When the wafer W is transported onto the spin chuck 21 of the processor 2A by the transport mechanism, the pins 24 are raised and lowered, and the wafer W is suctioned to the spin chuck 21, the shared developer nozzle 85 moves from the shared standby portion 87 to one of the left and right end portions on the cup 3. The shared developer nozzle 85 moves toward the other one of the left and right end portions on the cup 3 while ejecting the developer, and when the developer is supplied to the entire surface of the wafer W, the ejection of the developer is stopped. Then, the shared developer nozzle 85 returns toward the shared standby portion 87.

For example, regarding the shared developer nozzle 85, which has moved to the upper side of the cup 3 as described above, imaging is performed by the nozzle imaging camera 38 and the in-cup imaging camera 39 at an arbitrary time during the period from before the start of ejection of the developer to after the end of ejection of the developer. Then, as described above, it is determined whether there is an abnormality in the surface of the wafer W and the shared developer nozzle 85 based on the images acquired from each of these cameras 38 and 39.

When the shared developer nozzle 85 directed to the shared standby portion 87 passes through the upper side of the right standby portion 78, the cleaning liquid nozzle 76 is raised from the right standby portion 78 and moves to the upper side of the central portion of the wafer W, and the cup 3 is in the second state described with reference to FIG. 9. Then, the cleaning liquid nozzle 76 ejects the cleaning liquid, the wafer W rotates, the cleaning liquid flows toward the peripheral edge portion of the wafer W, and the developer is removed from the wafer W. Thereafter, while the ejection of the cleaning liquid is completed, the rotation of the wafer W is continued, the cleaning liquid is shaken off, and the wafer W is dried. The dried wafer W is delivered to the transport mechanism via the pins 24 and is carried out from the developing apparatus 1.

For example, regarding the cleaning liquid nozzle 76, which has moved to the upper side of the wafer W as described above, imaging is performed by the nozzle imaging camera 38 and the in-cup imaging camera 39 at an arbitrary time during the period from before the start of ejection of the cleaning liquid to after the end of ejection of the cleaning liquid. Then, as described above, it is determined whether there is an abnormality in the surface of the wafer W and the cleaning liquid nozzle 76 based on the images acquired from each of these cameras 38 and 39.

When using the cleaning liquid nozzle 76 following the shared developer nozzle 85 as described above, in order to prevent interference between the nozzles and the arms, the cleaning liquid nozzle 76 is not raised from the right standby portion 78 until the shared developer nozzle returning to the shared standby portion 87 passes through the upper side of the right standby portion 78 where the cleaning liquid nozzle 76 stands by. After the shared developer nozzle 85 has passed through the upper side of the right standby portion 78, the cleaning liquid nozzle 76 can be raised and moved to the upper side of the wafer W at an arbitrary time. For example, before the shared developer nozzle 85 starts to be lowered toward the shared standby portion 87 (i.e., before the shared developer nozzle 85 is accommodated in the shared standby portion 87), the cleaning liquid nozzle 76 may start to be raised so that processing efficiency is improved.

The operation when the developer nozzle 75 is used instead of the shared developer nozzle 85 will be described, focusing on the differences from the operation when the shared developer nozzle 85 is used. When the developer nozzle 75 is moved from the standby portion 77 to one of the right and left end portions of the wafer W in the first state of the cup 3, the cup 3 becomes the third state described with reference to FIG. 10. As the wafer W rotates, the developer nozzle 75 moves toward the other of the left and right end portions of the wafer W while ejecting the developer. When the supply position of the developer moves from one end portion of the wafer W to the central portion, and supply of the developer to the entire surface of the wafer W is completed, the ejection of the developer from the developer nozzle 75 and the rotation of the wafer W are stopped. In the case of using the developer nozzle 75 as well, as in the case of using the shared developer nozzle 85, for the developer nozzle 75 that has moved to the upper side of the wafer W, imaging is performed by the nozzle imaging camera 38 and the in-cup imaging camera 39 at an arbitrary time during the period from before the start of ejection of the developer to after the end of ejection of the developer. Then, it is determined whether there is an abnormality.

After the supply of the developer is completed, while the cup 3 returns to the first state and the developer nozzle 75 returns to the standby portion 77, the cleaning liquid nozzle 76 is moved from the standby portion 78 to the upper side of the central portion of the wafer W, and the cup 3 returns to the second state described with reference to FIG. 9. Thereafter, the processing proceeds in the same manner as the processing when the shared developer nozzle 85 is used. In addition, since the developer nozzle 75 does not pass through the upper side of the right standby portion 78 where the cleaning liquid nozzle 76 stands by when returning to the left standby portion 77, the cleaning liquid nozzle 76 may be raised from the right standby portion 78 to be moved to the upper side of the wafer W at an arbitrary time after the cup 3 returns to the first state.

In the above-described developing apparatus 1, in each of the processors 2A and 2B, a standby portion 77 for the developer nozzle 75 and a standby portion 78 for the cleaning liquid nozzle 76 are provided on the left and right sides of the cup 3, respectively, and the guide rail 73 is shared by the mover 71 for the developer nozzle 75 and the mover 72 for the cleaning liquid nozzle 76. Since the guide rail 73 is shared in this way, each of the developer nozzle 75 and the cleaning liquid nozzle 76 can be located above the central portion of the wafer W, so that the developer and the cleaning liquid can be supplied to the entire surface of the wafer W, as described above. Assuming that guide rails 73 are individually provided for the movers 71 and 72 such that the developer nozzle 75 and the cleaning liquid nozzle 76 can be respectively moved from the standby portions 77 and 78 to the upper side of the central portion of the wafer W, there is a concern that the size of the developing apparatus 1 is increased by arranging these guide rails 73 in the front and rear. That is, the developing apparatus 1 is configured to prevent an increase in size.

In the above-described example, one arm 74 is provided with only one nozzle, but a plurality of nozzles may be provided on one arm 74 so as to be arranged side by side, and one of the nozzles may be selected and used. Specifically, referring to the plan view of FIG. 11, nozzles 79 are arranged side by side on the arm 74 in place of the nozzles described above.

In order to supply a processing liquid to an entire wafer W, the nozzle 79 selected to eject the processing liquid will be located at least above the central portion of the wafer W and will eject the processing liquid to the central portion. Since the guide rail 73 is shared by the movers 71 and 72, the mover 71 can move rightward from the left side of the corresponding cup 3 to stand by the nozzles 79 of the arm 74 connected to the mover 71 beyond the central portion of the wafer W. Similarly, the mover 72 may move leftward from the right side of the corresponding cup 3 to stand by the nozzles 79 of the arm 74 connected to the mover 72 beyond the central portion of the wafer W. Therefore, even if a plurality of nozzles 79 are provided on one arm 74 as described above, a selected nozzle 79 can be located above the central portion of the wafer W to perform processing without any trouble. From the above, the configuration in which the guide rail 73 is shared by the movers 71 and 72 allows the number of nozzles provided in the apparatus to be relatively increased, thereby enabling various processes to be performed, so that the convenience as an apparatus is high.

The developing apparatus 1 has a layout in which, for both the processors 2A and 2B, the shared standby portion 87 where the developer nozzle 85 shared by the processors 2A and 2B is located on a side opposite to the sides where the spin chucks 21 are located when viewed from the standby portions where the nozzles dedicated to the processors 2 stand by in the left-right direction. With this layout, since it is possible to decrease a period of time required for moving the shared developer nozzle 85 from the shared standby portion 87 to each of the wafer W in the processor 2A and the wafer W in the processor 2B, a decrease in throughput can be prevented.

### Second Embodiment

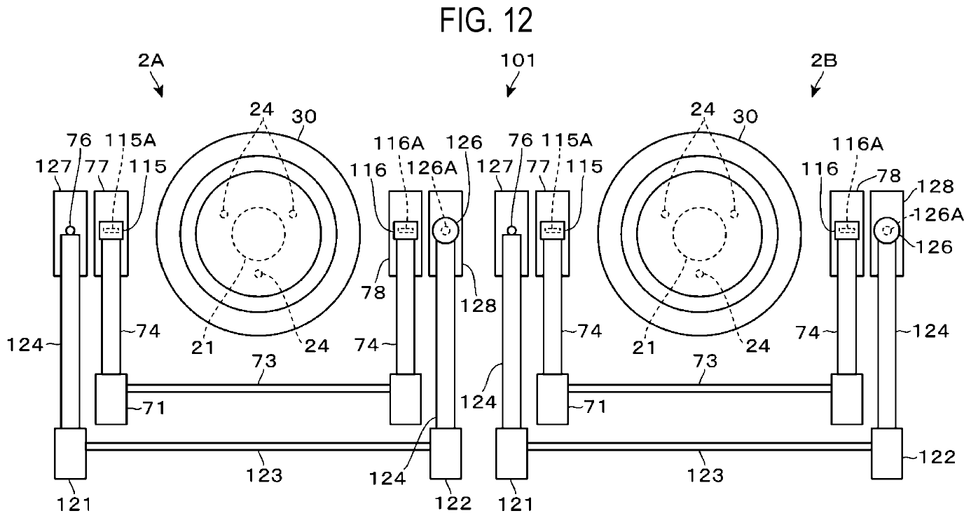

Next, a developing apparatus 101 according to a second embodiment will be described with reference to FIG. 12, focusing on differences from the developing apparatus 1 according to the first embodiment. In the drawing, illustration of some of the members configured in the same manner as the developing apparatus 1, such as the exhaust duct 28, the base bodies 26 that support the cups, the nozzle imaging cameras 38, the in-cup imaging cameras 39, and the housing 19, are omitted. Therefore, in the developing apparatus 101, exhaust is also performed through the same paths as the developing apparatus 1, and imaging of the nozzles are performed by the cameras 38 and 39. The developing apparatus 101 differs from the developing apparatus 1 in the number of arms that support the nozzles. For example, the nozzle imaging camera 38 is provided for each arm, and imaging is performed for each nozzle in the same manner as the first embodiment to make a determination as to whether there is an abnormality.

In the developing apparatus 101, wafers W are developed by using either a positive developer or a negative resist developer (negative developer). In addition, the developing apparatus 101 is not provided with the shared mover 81, the shared guide rail 83, the shared arm 84, and the shared developer nozzle 85. In addition, cups 30 are provided instead of the cups 3 in the developing apparatus 101. In the developing apparatus 101, as in the developing apparatus 1, the processors 2A and 2B have the same configuration. Thus, hereinafter, the processor 2A will be described as a representative. The arm 74 connected to the mover 71 and the arm 74 connected to the mover 72 are provided with a developer nozzle 115 configured to eject a positive developer and a developer nozzle 116 configured to eject a negative developer, respectively, instead of the nozzles described in the first embodiment. These developer nozzles 115 and 116 are provided with, for example, slits extending in the left-right direction as ejection ports 115A and 116A, respectively, and supply the developers to the entire surface of the wafer W by ejecting the developers while moving from the peripheral edge portion to the central portion of the rotating wafer W.

In addition, the developing apparatus 101 is provided with movers 121 and 122, a guide rail 123, and arms 124, which are configured in the same manner as the movers 71 and 72, the guide rail 73, and the arms 74, respectively. Therefore, the guide rail 123 is shared by the movers 121 and 122, and the movers 121 and 122 are movable in the left-right direction along the guide rail 123 and are able to raise and lower the connected arms 124, respectively. The guide rail 123 is provided in front of the guide rail 73, and the movers 121 and 122 move on the front side of the movement regions of the movers 71 and 72.

A cleaning liquid nozzle 76 is provided on the tip side of the arm 124 connected to the mover 121, and a developer nozzle 126 is provided on the tip side of the arm 124 connected to the mover 122. The developer nozzle 126 has a circular bottom surface and an ejection port 126A opening in the center of the bottom surface, and supplies the developer to the entire surface of the wafer W by ejecting the developer while moving from the peripheral edge portion to the central portion of the rotating wafer W while bringing the bottom surface thereof close to the surface of the wafer W. The developer ejected from the developer nozzle 126 is, for example, a positive type.

In the developing apparatus 101, the left standby portion 77 and the right standby portion 78 are used to make the developer nozzles 115 and 116 stand by, respectively. In addition, the developing apparatus 101 is provided with standby portions 127 and 128, which have the same configurations as the left standby portion 77 and the right standby portion 78, respectively. In order to distinguish between the standby portions, the standby portions 127 and 128 may be referred to as an outer left standby portion 127 and an outer right standby portion 128. The cleaning liquid nozzle 76 and the developer nozzle 126 are on standby while being accommodated in the outer left standby portion 127 and the outer right standby portion 128, respectively. The outer left standby portion 127 is disposed on the left side of the left standby portion 77, and the outer right standby portion 128 is disposed on the right side of the right standby portion 78. Therefore, the outer left standby portion 127, the left standby portion 77, the cup 30, the right standby portion 78, and the outer right standby portion 128 are arranged from the left side to the right side in this order. The outer left standby portion 127 and the outer right standby portion 128 are also arranged at the same height as the left standby portion 77 and the right standby portion 78, and each nozzle moves in the movement region R1 described with reference to FIG. 3, so that the heights of respective nozzles overlap when moving in the left-right direction.

With the above-described configuration, in the developing apparatus 101, each of the movers 71, 72, 121, and 122 is used to transport a nozzle from the standby portion to the upper side of the wafer W, so that development process with the positive developer or development process with the negative developer followed by cleaning process can be performed. When using the positive developer, one of the developer nozzles 115 and 126 is selected and used. When one of positive type development and negative type development is selected and performed in this manner, with respect to the cup 30, instead of changing the height as in the cup 3, a flow path is switched between the processing with the positive developer and the processing with the negative developer by a member that moves up and down inside the cup 30. As a result, the cup 30 is configured such that the positive developer and the negative developer can be discharged through different paths.

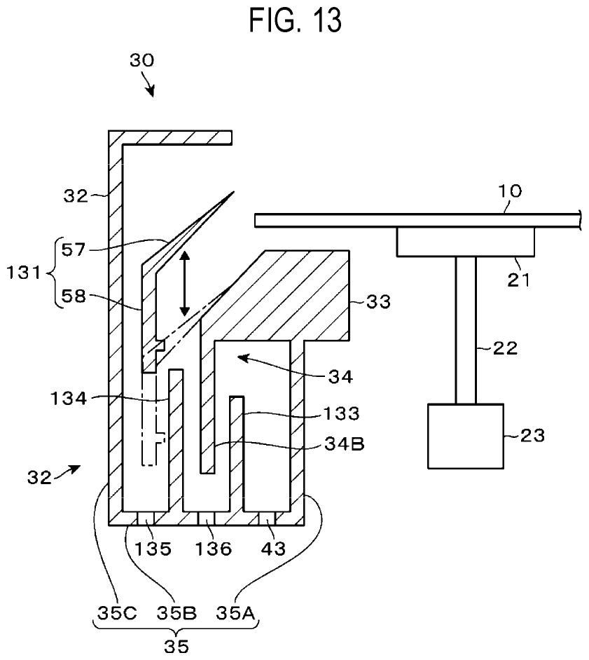

FIG. 13 is a vertical cross-sectional side view of the cup 30. A difference from the cup 3 is that the cup 30 includes a cup main body 32 and a circular annular portion 131. However, since the cup main body 32 is not provided with the quadrilateral perimeter wall 31 and the liquid receiving portion 36, the cup main body 32 has a circular shape in a plan view. The circular annular portion 131 has the same configuration as the lower circular annular portion 51 except that the sealing recess 59 is not formed at the lower end. An inner vertical wall 133 and an outer vertical wall 134 extending upward are provided in this order from the center side of the bottom wall 35B to divide the region on the bottom wall 35B of the cup main body 32 into three regions in the radial direction, wherein the inner vertical wall 133 is located inside the vertical wall 34B of the cup main body 32, and the outer vertical wall 134 is located between the vertical wall 34B and the barrel portion 58 of the circular annular portion 131. An exhaust port 43 is opened in the innermost region among the three regions divided in the bottom wall 35B, a drainage port 135 for a negative developer is opened in the outermost region, and a drainage port 136 for a positive developer is opened in the intermediate region between the innermost and outermost regions.

The circular annular portion 131 is raised and lowered with respect to the cup main body 32 by a lifting mechanism (not illustrated). When processing with the positive developer is performed, the circular annular portion 131 moves to the upper position indicated by the solid line in the drawing and receives the positive developer scattered from the wafer W on its inner peripheral surface, and the positive developer is guided to the drainage port 136. When processing with the negative developer is performed, the circular annular portion 131 moves to the lower position indicated by the dashed line in the drawing and receives the negative developer scattered by the outer wall 35C of the cup main body 32, and the negative developer is guided to the drainage port 135.

In the first and second embodiments, the shapes of the nozzles provided in the arms 74 and 124 and the shared arm 84 or the types of processing liquids to be ejected may be changed as appropriate. Therefore, with respect to the examples described above, the arrangement of the nozzles may be replaced, or an arbitrary processing liquid may be ejected from a nozzle having a shape different from the shape described for ejecting the processing liquid. Therefore, the first embodiment adopts the configuration in which the nozzles 75 and 76 connected to the movers 71 and 72 sharing the guide rail 73 in the example described above eject different processing liquids (a developer and a cleaning liquid), but, for example, by adopting a configuration in which the developer is ejected from both the nozzles, and making the nozzle 85 shared by the processors 2A and 2B eject the cleaning liquid, different types of processing liquids may be supplied to the wafers W in the respective processors 2A and 2B. That is, it may be possible to adopt a configuration in which the same processing liquid is ejected from the nozzles connected to the respective movers that share the guide rail 73, while different processing liquids are supplied to the wafers W within the same processor.

As described above, the developing apparatus 1 of the first embodiment and the developing apparatus 101 of the second embodiment are capable of transporting desired nozzles by using three or four arms and four movers for one cup 3. In addition, as described with reference to FIG. 11, the number of nozzles provided for an arm is not limited to one. Therefore, it is highly convenient because a wide variety of processes can be performed. As described above, the developing apparatuses 1 and 101 can be provided in a plurality of stages in a region having a relatively small height. When the developing apparatuses 1 and 101 provided in a plurality of stages are collectively viewed as one apparatus, a wide variety of processes can be performed with high throughput.

As will be described later, the developing apparatuses 1 and 101 are not limited to being configured to perform development process. It may be considered that depending on processing to be performed, there may be a case where it is necessary to move both one nozzle and another nozzle connected to different arms to the upper side of the cup 3 to perform the processing. In that case, one nozzle may be connected to an arm provided to make the one nozzle stand by in the standby portion on the left side of the cup 3, while the other nozzle may be connected to an arm provided to make the other nozzle stand by in the standby portion on the right side of the cup 3. Then, each of the nozzles may be disposed on the wafer W by moving the one nozzle rightward from the standby portion while moving the other nozzle leftward from the standby portion. That is, as described with reference to FIG. 3, although each nozzle moves in the movement region R1 and the movement heights of the nozzles are overlapped, it is possible not only to arrange the nozzles above the wafer W in order, but also to transport the nozzles above the wafer W at the same time by appropriately selecting the arms on which respective nozzles are provided.

In the first embodiment, one mover (shared mover) 81 is connected to the shared guide rail 83 and is moved by the shared guide rail 83, but a plurality of movers may be provided. For example, it is assumed that a mover 82 is provided in addition to the mover 81 and that a nozzle is connected to the mover 82 via an arm 84 as in the case of the mover 81. Assuming that this nozzle is a nozzle 89, a standby portion 88 where the nozzle 89 is allowed to stand by is provided between the cup 3 of the processor 2A and the cup 3 of the processor 2B, so that the standby portion 87 for the nozzle 85 connected to the mover 81 and the standby portion 88 for the nozzle 89 connected to the mover 82 are arranged side by side between the cups 3. By doing so, the wafer W in the processor 2A or 2B can be processed by using the nozzles 85, 89, 76, and 77. As described above, the guide rail 83 shared by the processors 2A and 2B is not limited to being configured to be used for guiding only one mover, and may be configured to be shared by a plurality of movers, whereby the convenience of the apparatus can be further enhanced.

Although a developer and a cleaning liquid are exemplified as the processing liquids used in the apparatus, the liquids are not limited thereto. For example, a coating liquid for forming a coating film such as a resist, a chemical for forming an insulating film, or a chemical for forming an antireflection film may be used, or an adhesive for bonding a plurality of wafers W may be used. Therefore, the liquid processing apparatus of the present technology is not limited to the developing apparatus.

Moreover, although the examples in which two processors are provided have been illustrated, three or more processors may be provided side by side. In the first embodiment, the mover 81, the arm 84, and the developer nozzle 85 are shared by the two processors 2A and 2B, but may be shared three or more processors when the three or more processors are provided. In addition, the exhaust duct 28 may have a configuration of extending in the left-right direction on the rear side of each cup 3 or each cup 30 so as to be connected to the base body 26 below each cup 3 or each cup 30. Also, although the cups 3 and 30 have been exemplified for the configurations of the cups, the configurations of the cups are arbitrary and may be appropriately selected depending on the processing to be performed by the apparatus. In addition, with respect to the above-described cup main body 32, the cup 3 is not limited to the configuration in which each of the lower circular annular portion 51 and the upper circular annular portion 61 are raised and lowered. A configuration in which, with respect to one of the cup main body 32, the lower circular annular portion 51 and the upper circular annular portion 61, the other two are raised and lowered may be possible. Furthermore, the substrate to be processed is not limited to a wafer W, and may be, for example, a substrate for manufacturing a flat display panel.

It is to be considered that the embodiments disclosed herein are exemplary in all respects and not restrictive. The above-described embodiments may be omitted, replaced, modified, and combined in various forms without departing from the scope and spirit of the appended claims.

The present disclosure is able to provide an apparatus that is highly convenient for performing liquid processing on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A liquid processing apparatus provided with a plurality of processors arranged in a left-right direction, wherein each of the plurality of processors comprises:
a stage on which a substrate is placed;
a cup surrounding the stage and the substrate placed on the stage;
a first processing nozzle and a second processing nozzle configured to supply a first processing liquid and a second processing liquid to the substrate, respectively;
a first standby portion where the first processing nozzle is allowed to stand by on one of left and right sides of the cup;
a second standby portion where the second processing nozzle is allowed to stand by on the other of the left and right sides of the cup;
a first mover configured to move the first processing nozzle between the first standby portion and a first processing position above the substrate;
a second mover configured to move the second processing nozzle between the second standby portion and a second processing position above the substrate; and
a guide shared by the first mover and the second mover such that each of the first mover and the second mover moves in the left-right direction.

2. The liquid processing apparatus of claim 1, wherein the first processing liquid and the second processing liquid are different types of processing liquids.

3. The liquid processing apparatus of claim 1, wherein, in each of the plurality of processors, the guide is provided on a front side of the cup, and the first mover and the second mover move in the left-right direction on the front side with respect to the cup, and
wherein the liquid processing apparatus further comprises:
a third processing nozzle configured to supply a third processing liquid to the substrate in one processor among the plurality of processors;
a third standby portion where the third processing nozzle is allowed to stand by, the third standby portion being provided on a side opposite to a side where the stage is located with respect to the first standby portion or the second standby portion in the one processor; and
a third mover configured to move in the left-right direction on a front side of the cup of the one processor and to move the third processing nozzle between the third standby portion and a third processing position above the substrate.

4. The liquid processing apparatus of claim 3, wherein the third processing nozzle is shared by the one processor and another processor among the plurality of processors,
the third standby portion is provided between the one processor and the another processor, and
the third mover moves in the left-right direction between the front side of the cup of the one processor and a front side of a cup of the another processor.

5. The liquid processing apparatus of claim 1, further comprising:
an exhaust path forming member configured to form an exhaust path extending from a rear side of a cup at one of left and right ends of a plurality of cups to a rear side of a cup at the other of the left and right ends in order to exhaust each of interiors of the plurality of cups,
wherein a downstream side of the exhaust path is an exhaust path shared by the plurality of cups.

6. The liquid processing apparatus of claim 1, further comprising:
a first imager and a second imager configured to respectively image the first processing nozzle and the second processing nozzle in the each of the plurality of processors in mutually intersecting directions.

7. The liquid processing apparatus of claim 1, further comprising:
a first annular body and a second annular body each of which surrounds the substrate placed on the stage in a plan view, the second annular body overlapping the first annular body from a space above the first annular body; and
a first lifting mechanism and a second lifting mechanism configured to relatively raise and lower the first annular body and the second annular body, respectively, with respect to the cup,
wherein the second lifting mechanism is raised and lowered together with the first annular body by the first lifting mechanism.

8. The liquid processing apparatus of claim 7, further comprising:
a perimeter wall that surrounds the first annular body and the second annular body in a plan view and has a notch formed in the perimeter wall,
wherein the first lifting mechanism comprises a first lifter configured to relatively move up and down outside the perimeter wall,
wherein the second lifting mechanism comprises a second lifter configured to relatively move up and down relative to the first lifter outside the perimeter wall,
wherein a first connector that connects the first lifter and the first annular body and a second connector that connects the second lifter and the second annular body are provided, and
wherein a state in which the notch is closed by at least one of the first connector and the second connector and a state in which the notch is opened are switched by up and down movement of the first lifter.

9. A liquid processing method using a liquid-processing apparatus including a plurality of processors arranged in a left-right direction, wherein each of the plurality of processors includes a stage on which a substrate is placed; a cup surrounding the stage and the substrate placed on the stage; a first processing nozzle and a second processing nozzle configured to supply a first processing liquid and a second processing liquid to the substrate, respectively; a first standby portion where the first processing nozzle is allowed to stand by on one of left and right sides of the cup; a second standby portion where the second processing nozzle is allowed to stand by on the other of the left and right sides of the cup; a first mover configured to move the first processing nozzle between the first standby portion and a first processing position above the substrate; a second mover configured to move the second processing nozzle between the second standby portion and a second processing position above the substrate; and a guide shared by the first mover and the second mover such that each of the first mover and the second mover moves in the left-right direction,
wherein the liquid processing method comprises:
moving, in the each of the plurality of processors, the first processing nozzle between the first standby portion and the first processing position and moving the second processing nozzle between the second standby portion and the second processing position, respectively; and
processing, in the each of the plurality of processors, the substrate by supplying, to the substrate, the first processing liquid and the second processing liquid from the first processing nozzle and the second processing nozzle, respectively.
